(19) United States
(12) Patent Application Publication
(10) Pub. No.: US 2022/0158108 A1
(43) Pub. Date: May 19, 2022

(54) LIGHT-EMITTING ELEMENT AND DISPLAY DEVICE USING LIGHT-EMITTING ELEMENT

(71) Applicant: SHARP KABUSHIKI KAISHA, Sakai City, Osaka (JP)

(72) Inventors: HIROFUMI YOSHIKAWA, Sakai City, Osaka (JP); TATSUYA RYOHWA, Sakai City, Osaka (JP); Masaki YAMAMOTO, Sakai City, Osaka (JP); TAKAHIRO DOE, Sakai City, Osaka (JP)

(21) Appl. No.: 17/434,347

(22) PCT Filed: Feb. 27, 2019
(86) PCT No.: PCT/JP2019/007531

§ 371 Date: Aug. 26, 2021

(51) Int. Cl. H01L 51/50

(52) U.S. Cl. CPC H01L 51/502; H01L 27/3244; H01L 2251/558; H01L 2251/301

(57) ABSTRACT

A light-emitting element includes: an anode; a cathode; and a light-emitting layer between the anode and the cathode, wherein the light-emitting layer contains quantum dots, and the quantum dots have a number average particle diameter greater than or equal to D_{LO2} and less than or equal to 100 nm, where D_{LO2} is a particle diameter of the quantum dots when the quantum dots exhibit an energy gap, between a ground state and a first excited state of a conduction band thereof, that is equivalent to twice an LO phonon energy of a material for the quantum dots.

### TECHNICAL FIELD

The present invention relates to light-emitting elements and display devices using a light-emitting element.

### BACKGROUND ART

Quantum dot-based tight-emitting elements are expected to be applied to display devices (see, for example, Patent Literature 1).

### CITATION LIST

### Patent Literature

Patent Literature 1: Japanese Unexamined Patent Application Publication, Tokukai, No. 2013-157180

### Non-Patent Literature

Non-Patent Literature 1: PHYSICAL REVIEW B 82, 195321 2010

### SUMMARY OF INVENTION

### Technical Problem

Quantum dot-based light-emitting elements however have an issue of low light-emission efficiency.

Accordingly, the present invention, in an aspect thereof, has an object to provide a light-emitting element and a display device that have a higher light-emission efficiency than conventional light-emitting elements and display devices.

### Solution to Problem

To achieve the object, the present invention, in an aspect thereof, is directed to a light-emitting element including: an anode; a cathode; and a light-emitting layer between the anode and the cathode, wherein the light-emitting layer contains quantum dots, and the quantum dots have a number average particle diameter greater than or equal to D_{LO2} and less than or equal to 100 nm, where D_{LO2} is a particle diameter of the quantum dots when the quantum dots exhibit an energy gap, between a ground state and a first excited state of a conduction band thereof, that is equivalent to twice an LO phonon energy of a material for the quantum dots.

To achieve the object, the present invention, in another aspect thereof, is directed to a light-emitting element including: an anode; a cathode; and a light-emitting layer between the anode and the cathode, wherein the light-emitting layer contains quantum dots, the quantum dots each contain Cd and Zn, and the quantum dots have a number average particle diameter greater than or equal to 14 nm and less than or equal to 100 nm.

To achieve the object, the present invention, in yet another aspect thereof, is directed to a light-emitting element including: an anode; a cathode; and a light-emitting layer between the anode and the cathode, wherein the light-emitting layer contains quantum dots, the quantum dots are made of CdS, and the quantum dots have a number average particle diameter greater than or equal to 9 nm and less than or equal to 100 nm.

To achieve the object, the present invention, in still another aspect thereof, is directed to a display device including the light-emitting element according to any one of the aspects thereof.

### Advantageous Effects of Invention

The present invention, in an aspect thereof, can provide a light-emitting element and a display device that have a higher light-emission efficiency than conventional light-emitting elements and display devices.

### BRIEF DESCRIPTION OF DRAWINGS

FIG. 1 is a schematic diagram of an exemplary layered structure of a display device in accordance with an embodiment of the present invention.

FIG. 2 is a schematic diagram of the structure of a liquid composition used to form a light-emitting layer in the display device in accordance with the embodiment of the present invention.

Portions (a) to (c) of FIG. 3 are energy band diagrams illustrating the mechanism of light emission by quantum dots in the display device in accordance with the embodiment of the present invention.

FIG. 4 is a graph representing a relationship between the particle diameter of quantum dots in the display device in accordance with the embodiment of the present invention and the energy gap between the ground and first excited states of the conduction band of the quantum dots when the quantum dots are made of CdS.

FIG. 5 is a graph representing a relationship between the particle diameter of quantum dots of Example 1 and the energy gap between the ground and first excited states of the conduction band of the quantum dots.

FIG. 6 is a graph representing a relationship between the particle diameter of quantum dots of Example 1 and the emission wavelength of the quantum dots.

FIG. 7 is a graph representing a relationship between the particle diameter of quantum dots of Example 2 and the energy gap between the ground and first excited states of the conduction band of the quantum dots.

FIG. 8 is a graph representing a relationship between the particle diameter of quantum dots of Example 2 and the emission wavelength of the quantum dots.

FIG. 9 is a graph representing a relationship between the particle diameter of quantum dots of Example 3 and the energy gap between the ground and first excited states of the conduction band of the quantum dots.

FIG. 10 is a graph representing a relationship between the particle diameter of quantum dots of Example 3 and the emission wavelength of the quantum dots.

FIG. 11 is a graph representing a relationship between the particle diameter of quantum dots of Example 4 and the energy gap between the ground and first excited states of the conduction band of the quantum dots.

FIG. 12 is a graph representing a relationship between the particle diameter of quantum dots of Example 4 and the emission wavelength of the quantum dots,

FIG. 13 is a graph representing a relationship between the particle diameter of quantum dots of Example 5 and the energy gap between the ground and first excited states of the conduction band of the quantum dots.

FIG. 14 is a graph representing a relationship between the particle diameter of quantum dots of Example 5 and the emission wavelength of the quantum dots.

FIG. 15 is a graph representing a relationship between the particle diameter of quantum dots of Example 6 and the energy gap between the ground and first excited states of the conduction band of the quantum dots.

FIG. 16 is a graph representing a relationship between the particle diameter of quantum dots of Example 6 and the emission wavelength of the quantum dots.

### DESCRIPTION OF EMBODIMENTS

FIG. 1 is a schematic diagram of an exemplary layered structure of a display device 1 in accordance with an embodiment of the present invention.

Referring to FIG. 1, the display device 1 in accordance with the present embodiment is a QLED display device including quantum-dot light-emitting diodes (hereinafter, “QLEDs”) as light-emitting elements 10. The display device 1 has a structure where a light-emitting element layer including plural types of light-emitting elements 10 that exhibit different emission wavelengths is disposed on a substrate 17.

Each light-emitting element 10 includes: a first electrode 11; a second electrode 16; and a hole injection layer 15, a hole transport layer 14, a light-emitting layer 13, and an electron transport layer 12 arranged in this order between the first electrode 11 and the second electrode 16 when viewed from the second electrode 16. In the example shown in FIG. 1, the first electrode 11 serves as a cathode, and the second electrode 16 serves as an anode.

The display device 1 includes a power supply 18. The first electrode 11 and the second electrode 16 are connected to the power supply 18 (e.g., a DC power supply as shown in FIG. 1), so that a voltage is applied across the first and second electrodes 11 and 16.

The substrate 17 is an array substrate carrying, for example, a thin film transistor (TFT) layer as a drive element layer thereon. The TFT layer includes, as a subpixel circuit, a drive circuit including TFTs or like drive elements that drive the light-emitting elements 10.

The second electrode 16, the hole injection layer 15, the hole transport layer 14, the light-emitting layer 13, and the electron transport layer 12 are separated by insulation layers (not shown) for each subpixel. The light-emitting element layer includes QLEDs as the light-emitting elements 10, each associated with a different subpixel. The second electrodes 16 provide a patterned anode for each subpixel as described here and are electrically connected to the respective TFTs on the substrate 17. On the other hand, the first electrode 11 is not separated by the insulation layers and provides a common cathode across the subpixels. The insulation layers serve both as subpixel separation walls and as edge covers covering the rims (edges) of the second electrodes 16. The insulation layers are made of, for example, an insulating material such as an acrylic resin or a polyimide resin. This structure is a mere example and does not limit the scope of the invention. For instance, the electron transport layer 12 may be common to all the subpixels. The first electrode 11 may provide a common anode, the second electrodes 16 may provide a patterned cathode for each subpixel, and the electron transport layer 12, the light-emitting layer 13, the hole transport layer 14, and the hole injection layer 15 may be stacked in this order between the first electrode 11 and the second electrode 16 when viewed from the second electrode 16.

The display device 1 includes, for example, red subpixels (R subpixels) that emit red light (R light), green subpixels (G subpixels) that emit green light (G light), and blue subpixels (B subpixels) that emit blue light (B light) as the subpixels.

Each R subpixel includes a red QLED (R QLED) as the light-emitting element 10 that emits R light. Each G subpixel includes a green QLED (G QLED) as the light-emitting element 10 that emits G light. Each B subpixel includes a blue QLED (B QLED) as the light-emitting element 10 that emits B light.

For the purpose of this specification, R light refers to light having a central emission wavelength in the range of in excess of 600 nm and less than or equal to 780 nm, preferably light having a wavelength in the range of 625 to 635 nm (or 630 nm±5 nm) which extends across the red wavelength (=630 nm) specified under the BT. 2020 international standard; G light refers to light having a central emission wavelength in the range of in excess of 500 nm and less than or equal to 600 nm, preferably light having a wavelength in the range of 527 to 537 nm (or 532 nm±5 nm) which extends across the green wavelength (=532 nm) specified under the BT. 2020 international standard; and B light refers to light having a central emission wavelength in the range of greater than or equal to 400 nm and less than or equal to 500 nm, preferably light having a wavelength in the range of 462 to 472 nm (or 467 nm±5 nm) which extends across the blue wavelength (=467 nm) specified under the BT. 2020 international standard.

Either one or both of the first electrode 11 and the second electrode 16 is/are transmissive and transmits the light emitted by the light-emitting layer 13. The substrate 17 may be made of a transmissive material or a reflective material.

When the light-emitting element 10 is of a top-emission type where light is discharged through the first electrode 11, the first electrode 11 is transmissive, and the second electrode 16 is reflective. On the other hand, the light-emitting element 10 is of a bottom emission type where light is discharged through the second electrode 16, the second electrode 16 is transmissive, and the first electrode 11 is reflective. The light-emitting element 10 may alternatively be of a top and bottom emission type where the first electrode 11 and the second electrode 16 are both transmissive.

These transmissive electrodes are composed primarily of, fir example, a transmissive conductive material. The reflective electrodes may be composed primarily of a metal that is highly reflective to visible light or an alloy containing such a metal and may be a stack body of a layer of primarily a transmissive conductive material and a layer of primarily a metal that is highly reflective to visible light or an alloy containing such a metal. Examples of the transmissive conductive material include ITO (indium tin oxide), IZO (indium zinc oxide), AZO (aluminum zinc oxide) and GZO (gallium zinc oxide). Examples of the metal that is highly reflective to visible light include Al (aluminum), Cu (copper), Au (gold), and Ag (silver).

The electron transport layer 12, serving to enhance the efficiency of electron transport to the light-emitting layer 13, transports electrons from the second electrode 16 to the light-emitting layer 13. The electron transport layer 12 contains, for example, particles of a metal oxide such as ZnO (zinc oxide), TiO₂ (titanium oxide), MgZnO (magnesium zinc oxide), Ta₂O₃ (tantalum oxide), or SrTiO₃ (strontium titanium oxide). The electron transport layer 12 may contain particles of a metal oxide that is common to all the subpixels or particles of different metal oxides depending on the subpixels. The electron transport layer 12 may additionally serve as an electron injection layer to enhance the efficiency of electron injection from the first electrode 11 to the light-emitting layer 13.

The hole injection layer 15 serves to enhance the efficiency of hole injection to the hole transport layer 14. The hole transport layer 14, serving to enhance the efficiency of hole transport to the light-emitting layer 13, transports holes from the second electrode 16 to the light-emitting layer 13 via the hole injection layer 15.

The hole injection layer 15 and the hole transport layer 14 may contain, for example, an inorganic material such as nickel oxide (NiO) or molybdenum oxide (MoO₃) or an organic material such as PEDOT (polyethylenedioxythiophene), PEDOT-PSS (poly(3,4-ethylenedioxythiophene)-poly(styrenesulfonate)), TPD (4,4′-bis[N-phenyl-N-(3″-methylphenyl)amino]biphenyl), PVK (poly(N-vinylcarbazole)), TFB (poly[(9,9-dioctylfluorenyl-2,7-diyl)-co-(4,4′-(N-(4-sec-butylphenyl))diphenylamine)]), CBF (4,4′-bis(9-carbazoyl)-biphenyl), or NPD (N,N′-di-[(1-naphthyl)-N,N′-diphenyl]-(1,1′-biphenyl)-4,4′-diamine). The hole injection layer 15 and the hole transport layer 14 may be formed of a common material in all the subpixels or different materials depending on the subpixels.

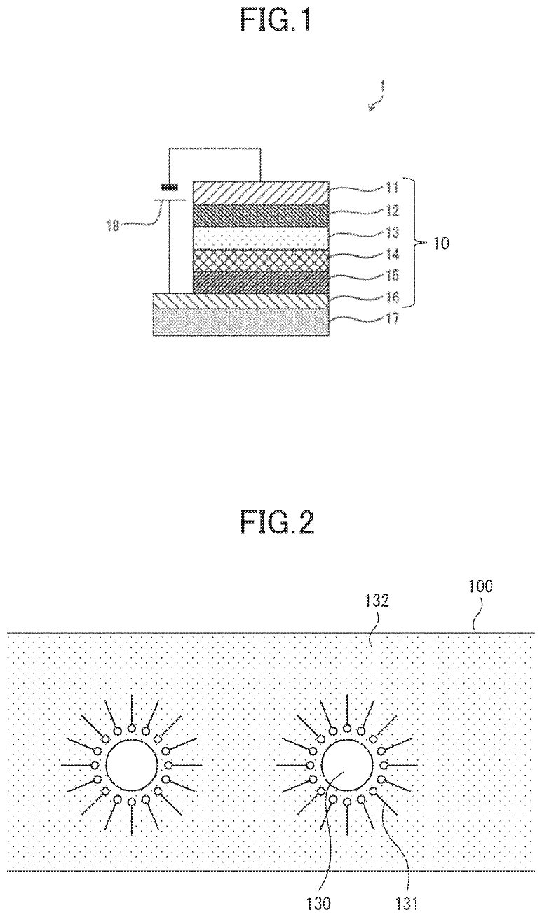

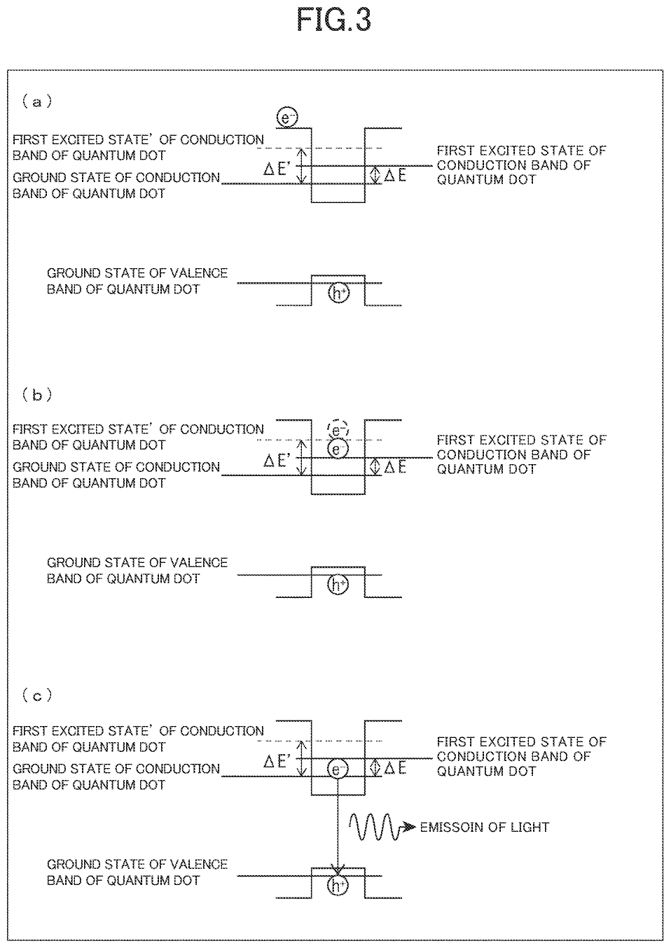

FIG. 2 is a schematic diagram of the structure of a liquid composition 100 used to form the light-emitting layer 13.

The light-emitting layer 13 is formed from the liquid composition 100 containing quantum dots (semiconductor nanoparticles; hereinafter, “QDs”) 130 dispersed in, for example, a prescribed medium 132 as shown in FIG. 2. The liquid composition 100 is a colloidal solution containing: the quantum dots (semiconductor nanoparticles; hereinafter, “QDs”) 130; ligands 131 on the surfaces of the quantum dots with the quantum dots as receptors; and the medium 132. Each ligand 131 has an adsorption group adsorbed (coordinated) to the surface of the QD 130 and an alkyl group attached to the adsorption group. The adsorption group may be, for example, an amino group, a phosphine group, a carboxyl group, a hydroxyl group, or a thiol group. The alkyl group may be, for example, a C₂C₅₀ alkyl group.

More specifically, the ligand 131 may be, for example, hexadecylamine, oleylamine, octyl amine, hexadecanethiol, dodecanethiol, trioctylphosphine, trioctylphosphine oxide, myristic acid, or oleic acid. The ligands 131 additionally serve as a dispersant that improves the dispersion of the QDs 130 in the liquid composition 100.

The medium 132 in the liquid composition 100 may be, for example, water or an organic solvent such as methanol, ethanol, propanol, butanol, pentane, hexane, octane, acetone, toluene, xylene, benzene, chloroform, dichloromethane, or chlonbenzene. The medium may be at least one liquid species selected from the group consisting of water and these organic solvents.

The light-emitting layer 13 can be formed by applying the liquid composition 100 to the top thee of the hole transport layer 14 to form a film of the liquid composition 100 and volatilizing the medium in the liquid composition 100 to solidify (cure) the film.

As can be understood from this description, the QDs 130 in the light-emitting layer 13 in accordance with the present embodiment are an application-type of QDs formed by a solution technique, not by crystal growth. The light-emitting layer 13 thus formed contains the spherical QDs 130 and the ligands 131. According to the present embodiment, the light-emitting layer 13 is capable of restraining the polarization of emission because the QDs 130 are shaped spherical, not convex as would be the case when the QDs are formed by crystal growth. In addition, the light-emitting layer 13, containing the ligands 131, is capable of suppressing aggregation of the QDs 130 so that the QDs 130 can be dispersed well when the liquid composition 100 is applied to form a film.

The light-emitting layer 13 contains the QDs 130 of different colors formed as described above as a light-emitting material in each subpixel. Specifically, the light-emitting layer 13 contains a red QD (RQD) in a R subpixel thereof, a green QD (GQD) in a G subpixel thereof, and a blue QD (BQD) in a B subpixel thereof, as the QDs 130. The RQD, GQD, and BQD emit light of different wavelengths. The QDs are, for example, QD fluorescent materials and emit R light, G light, and B light as, for example, fluorescence as mentioned earlier. The light-emitting layer 13 hence includes plural types of QDs as the QDs 130, a single type of QD 130 in each subpixel.

The QDs 130 used in the present embodiment, as will be described later, preferably exhibit an energy gap, between the ground and first excited states of the conduction band thereof, that is less than or equal to twice the longitudinal optical (LO) phonon energy of the QD material for the QDs 130 (i.e., from 0 times the LO phonon energy; exclusive, to 2 times the LO phonon energy, inclusive) and more preferably exhibit an energy gap therebetween that is less than or equal to the LO phonon energy (i.e., from 0 times the LO phonon energy, exclusive, to 1 time the LO phonon energy, inclusive).

In other words, the QDs 130 used in the present embodiment preferably have a number average particle diameter greater than or equal to D_{LO2}, where D_{LO2} is the particle diameter of the QDs 130 when the QDs 130 exhibit an energy gap, between the ground and first excited states of the conduction band thereof, that is equivalent to twice the LO phonon energy of the QD material for the QDs 130. In addition, the QDs 130 used in the present embodiment more preferably have a number average particle diameter greater than or equal to D_{LO1}, where D_{LO1} is the particle diameter of the QDs 130 when the QDs 130 exhibit an energy gap, between the ground and first excited states of the conduction band thereof, that is equivalent to 1 time the LO phonon energy of the QD material for the QDs 130 for the following reasons. “The particle diameter of the QDs 130 when the QDs 130 exhibit an energy gap, between the ground and first excited states of the conduction band thereof, that is equivalent to twice (or equivalent to 1 time) the LO phonon energy of the QD material for the QDs 130” refers to the particle diameter of the QDs 130 when the QDs 130 exhibit an energy gap, between the ground and first excited states of the conduction band thereof, that is equal to twice (or equal to 1 time) the LO phonon energy of the QD material for the QDs 130. “The number average particle diameter of the QDs 130” (hereinafter, simply “the average particle diameter”) refers to the number average diameter (number average diameter size) given by formula (1) that is one of the arithmetic mean diameters of the QDs 130.

[Math. 1]

Σ(nd)/Σn (1)

where d is a representative value for a particle diameter channel, and n is the particle-count-based percentage of a particle diameter channel.

Strictly speaking, the LO phonon energy of a QD material can vary depending on the size of the QDs. In general applications, however, the value of the LO phonon energy of a QD material in bulk form is employed as it is the case in Non-Patent Literature 1. The LO phonon energy of a ternary QD material can be uniquely calculated, for example, from a combination of the LO phonon energy values of known binary QD materials containing two of the three elements in the QD material. A decrease in the LO phonon energy reduces the particle diameter of the QDs 130, which in turn reduces the average particle diameter of the QDs 130.

Portions (a) to (c) of FIG. 3 are energy band diagrams illustrating the mechanism of light emission by the QDs 130. Portions (a) to (c) of FIG. 3 only show the ground and first excited states of the conduction band of the QDs 130 and the ground state of the valence band of the QDs 130 among the energy states of the QDs.

Holes and electrons are supplied to the light-emitting layer 13 from the second electrode 16 (anode) and the first electrode 11 (cathode) respectively under the drive current between the first electrode 11 and the second electrode 16. These holes and electrons recombine in the light-emitting layer 13, thereby emitting light.

When a voltage is applied across the first electrode 11 and the second electrode 16, Which causes a current to flow to the light-emitting layer 13, numerous holes and electrons are injected to the light-emitting layer 13 from the second electrode 16 and the first electrode 11 respectively. These holes and electrons flow into the QDs 130 where the band gap between the lower limit of the conduction band and the upper limit of the valence band (the width of the forbidden band). The holes and electrons are confined in the QDs 130. The QDs 130 exhibit the quantum confinement effect when the QDs 130 have a smaller particle diameter than the Bohr radius. The electrons in the conduction band and the holes in the valence band recombine to emit light in the QDs 130.

To describe it in more detail, the electrons (e⁻) supplied from the second electrode 16 to the light-emitting layer 13 shown in (a) of FIG. 3 first drop to the first excited state of the conduction band of the QDs 130 as shown in (b) of FIG. 3. The electrons then drop (relax) to the ground state of the conduction band of the QDs 130 as shown in (c) of FIG. 3. Thereafter, the electrons recombine with the holes (h⁺) that have made a transition to the ground state of the valence band of the QDs 130 after being supplied from the first electrode 11.

Conventional QD-based light-emitting elements have a poor efficiency of electron injection to the ground state of the conduction band of the QDs, which leads to a low light-emission efficiency. The QDs in the light-emitting elements have a relatively small size and exhibit strong quantum confinement effect. The inventors of the present invention have diligently worked to provide a light-emitting element that has a higher light-emission efficiency than conventional light-emitting elements and have found that the first excited state of the conduction band of the QDs affect the light-emission efficiency of the QDs.

Specifically, the inventors have found that one of the factors for the low light-emission efficiency of conventional light-emitting elements is that the relaxation time of the electron surrounded by a broken line in (b) of FIG. 3, in which the electron relaxes from the first excited state of the conduction band of the QD (indicated as the “first excited state′ of the conduction band” of the QD in FIG. 3) to the ground state of the valence band, is not sufficiently short when compared with the emission lifetime. The inventors have also found that for these reasons, reducing the relaxation time increases the efficiency of electron injection to the ground state of the conduction band of the QDs, which in turn increases the light-emission efficiency. The inventors have concluded that the relaxation time can be reduced by shifting the first excited state of the conduction band of the QDs 130 indicated by a solid line in (a) to (c) of FIG. 3 to a lower state than the first excited state′ of the conduction band of conventional QDs indicated by a broken line in (a) to (c) of FIG. 3, so that the energy gap ΔE between the ground and first excited states of the conduction band of the QDs is smaller than the energy gap ΔE′ between the ground and the first excited state′ of the conduction band of conventional QDs.

Non-Patent Literature 1 discloses, in FIG. 9, the relationship between the energy gap ΔE between the ground and first excited states of the conduction band of the QD and the LO phonon scattering time for GaAs when the QD material is GaAs (gallium arsenide) in a photoelectric conversion element in a solar cell. Non-Patent Literature 1, as described here, relates to solar cells and does not directly relate to the light-emitting elements used in the display device.

In view of the present invention, however, FIG. 9 of Non-Patent Literature 1 suggests that when the energy gap ΔE between the ground and first excited states of the conduction band of the QD is close to the LO phonon energy (36 meV), phonons quickly cause scattering of electrons (phonon scattering) (1×10⁻⁹ to 1×10⁻¹² s).

The LO phonon energy of GaAs is employed in Non-Patent Literature 1 as the LO phonon energy as described above. However, phonon scattering similarly occurs quickly near the LO phonon energy in other materials, such as InP (indium phosphide) which exhibits a 43-meV LO phonon energy.

Therefore, the LO phonons, which is one of optical phonons, can be more quickly scattered (LO phonon scattering) by reducing the energy gap ΔE between the ground and first excited states of the conduction band of the QD. LO phonon scattering hence allows for a shorter relaxation time.

In the present embodiment, the energy gap ΔE between the ground and first excited states of the conduction band of the QDs 130 is from 0 times the LO phonon energy of the material for the QDs 130, exclusive, to 2 times (preferably 1 time) the LO phonon energy, inclusive. Specifying the energy gap ΔE of the QDs 130 to from 0 times the LO phonon energy of the material for the QDs 130, exclusive, to 2 times the LO phonon energy, inclusive, in this manner allows for a shorter LO phonon scattering time than when there exists a strong quantum confinement effect. That in turn enables the carriers in the excited state to efficiently relax to the ground state. In addition, specifying the energy gap ΔE of the QDs 130 to less than or equal to 1 time the LO phonon energy of the material for the QDs 130 enables the carriers in the excited state to more efficiently relax to the ground state.

For instance, in the example shown in FIG. 9 of Non-Patent Literature 1, the energy gap ΔE of the QDs is from 0 times the LO phonon energy of the QD material for the QDs, exclusive, to 2 times the LO phonon energy, inclusive. This specification reduces the LO phonon scattering time by more than half in comparison with when the energy gap ΔE is 3 times the LO phonon energy of the material for the QDs.

The QDs typically have an emission lifetime of a few nanoseconds. Therefore, for example, when the energy gap ΔE of the QDs 130 is approximately 3 times the LO phonon energy of the QD material for the QDs 130, the scattering time (relaxation time) is approximately on the order of hundreds of nanoseconds (i.e., emission lifetime relaxation time) and will likely act as a bottleneck. Hence, when the energy gap ΔE of the QDs 130 is approximately 3 times the LO phonon energy of the QD material for the QDs, the light-emitting element 10 exhibits a low light-emission efficiency.

On the other hand, when the energy gap ΔE of the QDs 130 is less than or equal to twice the LO phonon energy of the QD material for the QDs 130, the scattering time (relaxation time) can be reduced to approximately tens of nanoseconds, which is sufficiently close to the emission lifetime. The scattering time varies by no less than an order of magnitude in this manner between when the energy gap ΔE of the QDs 130 is approximately 3 times the LO phonon energy of the QD material for the QDs 130 and when the energy gap ΔE is less than or equal to twice the LO phonon energy When the energy gap ΔE of the QDs 130 is less than or equal to twice the LO phonon energy of the QD material for the QDs 130, the light-emission efficiency will likely improve because the scattering time approaches the emission lifetime as described above.

In addition, when the energy gap ΔE of the QDs 130 is equal to the LO phonon energy of the QD material for the QDs 130 (i.e,, equal to 1 time the LO phonon energy), the scattering time (relaxation time) is approximately on the order of hundredths of nanoseconds (i.e., relaxation time<<emission lifetime), which means that the relaxation time is sufficiently shorter than the emission lifetime. The relaxation time hence does not act as a bottleneck, and the light-emission efficiency will likely improve significantly. Specifying the energy gap ΔE of the QDs 130 to less than or equal to 1 time the LO phonon energy of the QD material for the QDs 130 in this manner allows for a further reduction of the LO phonon scattering time.

It is expected also from FIG. 9 of Non-Patent Literature 1 that the LO phonon scattering time when the energy gap ΔE of the QDs is from 0 times the LO phonon energy of the QD material for the QDs, exclusive, to 1 time the LO phonon energy, inclusive, can be reduced at least to an equivalent of the LO phonon scattering time when the energy gap ΔE is 1 to 2 times the LO phonon energy.

Phonons include acoustic phonons (LA (longitudinal acoustic) phonons and TA (transverse acoustic) phonons) and optical phonons (LO phonons (described above) and TO (transverse optical) phonons).

Phonon scattering occurs efficiently owing also to acoustic phonons in energy levels lower than the LO phonon energy. Acoustic phonons have continuous energy and are for this reason efficiently phonon-scattered by LO phonons and acoustic phonons or by acoustic phonons in energy levels lower than the LO phonon energy. The scattering time is therefore as short as, or sufficiently shorter than, the emission lifetime in energy levels lower than the LO phonon energy, which sufficiently improves the light-emission efficiency.

The energy gap ΔE of the QDs 130 is dictated by the QD material and the particle diameter of the QDs. The LO phonon energy of the QD material is dictated by the QD material. Although strictly speaking, the LO phonon energy of the QD material is affected also by the particle diameter of the QDs, the value of the LO phonon energy of the QD material in bulk form is typically employed as it is the case with Non-Patent Literature 1. Additionally; although strictly speaking, the emission lifetime is affected also by the QD material and the particle diameter of the QDs, the emission lifetime remains on the same order of magnitude (at approximately a few nanoseconds).

The QDs 130 exhibit the quantum confinement effect when the QDs 130 have a smaller particle diameter than the Bohr radius, as described earlier. The confinement of a quantum to a QD produces discrete quantum energy states (quantum states) in the conduction band and the valence band of the quanta. The QD 130 emits light with a wavelength corresponding to the band gap (width of the forbidden band) and the quantum state (excited state) thereof. The QD 130 is spherical and has a substantially uniform particle diameter, as described earlier. The QD 130 emits light with a wavelength corresponding to the particle diameter of the QD 130.

The energy gap ΔE of the QD 130 changes with the particle diameter (i.e., the diameter of the core) of the QD 130. Specifically, an increase in the particle diameter of the QD 130 tends to decrease the energy gap ΔE of the QD 130 and increase the emission wavelength thereof, and a decrease in the particle diameter of the QD 130 tends to increase the energy gap ΔE of the QD 130 and decrease the emission wavelength thereof.

Therefore, the average value of the energy gap ΔE (average energy gap ΔE) of the QDs 130 can be reduced by increasing the average particle diameter of the QDs 130 in the light-emitting layer 13. It should be understood however that the emission wavelength increases when the average particle diameter of the QDs 130 in the light-emitting layer 13 is increased.

There exists an optimal emission wavelength when the light-emitting elements 10 are used in display devices as described earlier. For instance, under the BT. 2020 international standard, the central emission wavelength is 630 nm for red light, 532 nm for green light, and 467 nm for blue light, as described earlier.

For these reasons, when the light-emitting elements 10 are applied to the display device 1 as described above, the QD material and the average particle diameter of the QDs 130 need to be controlled in such a manner that the QDs 130 have an energy gap ΔE less than or equal to twice the LO phonon energy of the QD material for the QDs 130 and that translates into an appropriate emission wavelength.

In other words, when the light-emitting elements 10 are applied to the display device 1, it is necessary to select such a combination of the QD material and the particle diameter (more precisely, the average particle diameter) of the QDs that the QDs 130 have an energy gap ΔE less than or equal to twice the LO phonon energy of the QD material for the QDs 130 and that translates into an appropriate emission wavelength.

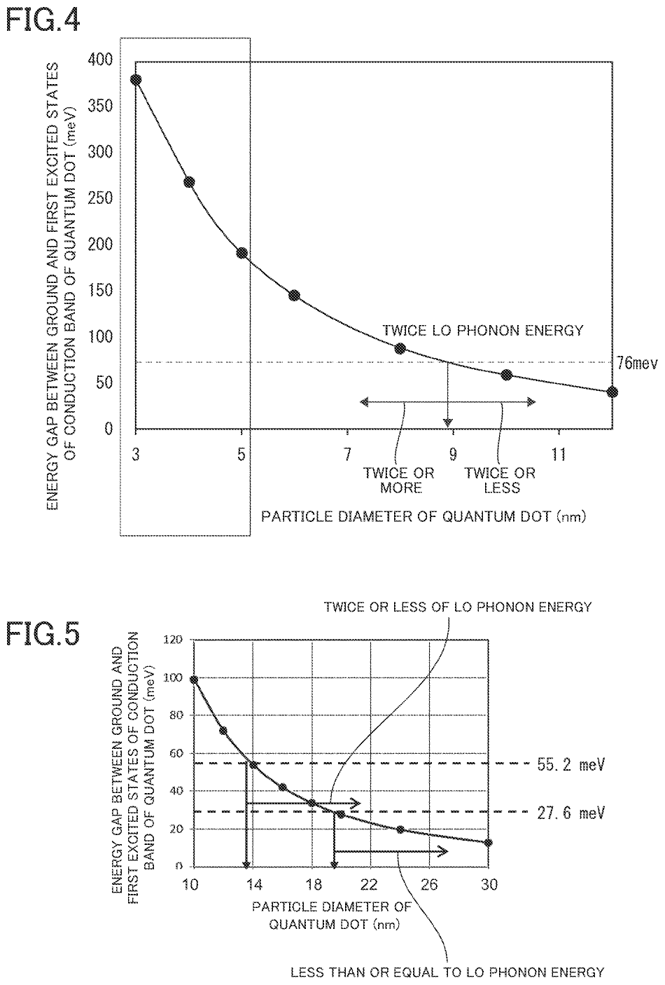

FIG. 4 is a graph representing a relationship between the particle diameter of QDs and the energy gap ΔE of the QDs when the QDs are made of CdS.

Typical QDs in conventional light-emitting elements have a particle diameter (average particle diameter) of, for example, approximately 3 to 5 nm as described in Patent Literature 1.

It is therefore understood from the framed part of FIG. 4 that the QDs made of CdS that have a conventionally typical particle diameter (average particle diameter) have an energy gap ΔE in excess of approximately 200 meV and sufficiently greater than 76 meV, which is twice the LO phonon energy (=38 meV) of CdS.

In other words, the publicly known CdS QDs has an energy gap ΔE greater than twice the LO phonon energy of CdS and for this reasons, out of the scope of the present embodiment. The QDs 130 in the present embodiment have a non-conventional, large particle diameter (average particle diameter) as described here.

An increase in the particle diameter of the QD increases the emission wavelength as described earlier. In addition, increasing the particle diameter of QDs can be a cause for QD defects in the current QD manufacturing technology (especially when QDs are made by, for example, crystal growth). Accordingly, the QDs currently in use are typically made of such a QD material that the resultant QDs emit light with a suitable wavelength when the QDs have an average diameter of approximately 3 to 5 nm.

Therefore, if the average diameter of the QDs made of the conventional, popularly used QD material is increased to improve the tight-emission efficiency, the emission wavelength can be too long for the QDs to be applied to display devices.

Some popular current QD materials are capable of providing a suitable emission wavelength (red, green, or blue) even when the resultant QDs have such an increased particle diameter as to have an energy gap ΔE corresponding to twice the LO phonon energy of the QD materials.

It is however not conventionally known that when the QDs have an energy gap ΔE of from 0 times the LO phonon energy of the material for the QDs, exclusive, to 2 times the LO phonon energy, inclusive, the electrons in the first excited state of the conduction band of the QDs efficiently relax to the ground state of the conduction band of the QDs, thereby achieving efficient emission.

Since increasing the particle diameter of QDs can be a cause for QD defects as described above, the conventional, popularly used QDs have as small a diameter as possible. This industrial practice involves no concept or motivation to increase the average diameter of the QDs.

Therefore, the light-emitting layer in conventional light-emitting elements contains no QDs having an average particle diameter greater than or equal to such a particle diameter that the energy gap ΔE is twice the LO phonon energy of the QD material for the QDs. No combination is known of a QD material and such an increased particle diameter of QDs as to emit light with a wavelength suitable for display devices.

The QDs 130 preferably have as small an energy gap ΔE as possible to increase the efficiency of electron injection to the ground state of the conduction band of the QDs 130. Accordingly, there is no particular upper limit to the average particle diameter of the QDs 130 from the point of view of the efficiency of electron injection to the ground state of the conduction band of the QDs 130. The QDs 130 however preferably have an average particle diameter less than or equal to 100 nm because the QDs 130 may not be able to serve as quantum dots if the average particle diameter exceeds 100 nm.

The QDs 130 may include, for example, semiconductor nanoparticles made of a semiconductor material containing at least one element selected from the group consisting of Cd (cadmium), S (sulfur), Te (tellurium), Se (selenium), Zn (zinc), In (indium), N (nitrogen), P (phosphorus), As (arsenic), Sb (antimony), Al (aluminum), Ga (gallium), Pb (lead), Si (silicon), Ge (germanium), and Mg (magnesium),

The QDs 130 may alternatively include, for example, semiconductor nanoparticles made of a binary semiconductor material (binary mixed crystal) containing two elements or semiconductor nanoparticles made of a ternary semiconductor material (ternary mixed crystal) containing three elements.

Examples of the QDs 130 include those QDs that are made of a QD material containing Cd (cadmium) and Zn (zinc) and that have an average particle diameter greater than or equal to 14 nm and those QDs that are made of a QD material containing Cd and S (sulfur) and that have average particle diameter greater than or equal to 9 nm.

Examples of the QD material containing Cd and Zn include (Cd, Zn) Se-based QD materials of CdₓZn₁₋ₓSe containing Cd, Zn, and Se (selenium) and (Cd, Zn) Te-based QD materials of CdₓxZn₁₋ₓTe containing Cd, Zn, and Te (tellurium).

Specific examples of RQDs include those QDs that are made of Cd_{0.7}Zn_{0.3}Se and that have an average particle diameter greater than or equal to 14 nm and those QDs that are made of Cd_{0.55}Zn_{0.45}Te and that have an average particle diameter greater than or equal to 14 nm.

Specific examples of GQDs include those QDs that are made of Cd_{0.4}Zn_{0.6}Se and that have an average particle diameter greater than or equal to 13 nm and those QDs that are made of Cd_{0.1}Zn_{0.9}Te and that have an average particle diameter greater than or equal to 12 nm.

Specific examples of BQDs include those QDs that are made of Cd_{0.15}Zn_{0.85}Se and that have an average particle diameter greater than or equal to 13 nm and those QDs that are made of CdS (cadmium sulfide and that have an average particle diameter greater than or equal to 9 nm.

Although CdSe, as an example, is a known QD material as described in, for example, Patent Literature 1, CdSe QDs with an increased average particle diameter do not emit light in the visible range which is required in display devices. However, these QDs can be used in the light-emitting elements 10 in the display device 1 when Zn is added to CdSe and the blend ratio of these elements (i.e., the QD composition ratio) and the average particle diameter of the QDs are specified as described earlier.

In the display device 1, for example, all the QD materials for the QDs 130 (specifically, RQDs, GQDs, and BQDs) in the light-emitting layer 13 in the subpixels (R, G, and B subpixels) preferably contain Cd, Zn, and Se. In such a case, the composition ratio (blend ratio) of Zn in the QDs 130 in the subpixels is increased for shorter emission wavelengths. As an example, the RQDs are made of Cd_{0.7}Zn_{0.3}Se, the GQDs are made of Cd_{0.4}Zn_{0.6}Se, and the BQDs are made of Cd_{0.15}Zn_{0.85}Se, as described earlier. The present embodiment provides an RGB full-color display using a single material system by simply varying the composition ratio (blend ratio) of Zn represented by (1−x) in CdₓZn₁₋ₓSe in this manner so as to satisfy R<G<B.

In addition, in the display device 1, for example, all the QD materials for the QDs 130 in the light-emitting layer 13 in at least two types of subpixels preferably contain Cd, Zn, and Te. In such a case, the composition ratio (blend ratio) of Zn in the QDs 130 in the subpixels is increased for shorter emission wavelengths as in the preceding case. As an example, the RQDs are made of Cd_{0.55}Zn_{0.45}Te, and the GQDs are made of Cd_{0.1}Zn_{0.9}Te, as described earlier. The present embodiment provides R and G emission using a single material system by simply varying the composition ratio (blend ratio) of Zn represented by (1−x) in CdₓZn₁₋ₓTe in this manner so as to satisfy, for example, R<G.

In the present embodiment, the ratio of elements in the QD material for the QDs 130 is not limited in any particular manner. The ratio may be specified in a suitable manner such that the QDs 130 can emit light with a desirable wavelength when the QDs 130 has an average particle diameter of from D_{LO2} to 100 nm, both inclusive, where Dun is, as described earlier, the particle diameter of the QDs 130 when the QDs 130 exhibit an energy gap ΔE, between the ground and first excited states of the conduction band thereof, that is equivalent to twice the LO phonon energy of the QD material.

The quantum states of the conduction band and the valence band of the QDs 130 can be calculated by solving a single-band Schrodinger equation. The LO phonon energy of a ternary QD material can be calculated, for example, from a combination of the LO phonon energy values of known binary QD materials containing two of the three elements in the QD material. The relationship between the energy gap ΔE of the QDs 130 and the average particle diameter of the QDs 130 can be determined from an energy gap between the ground and first excited states of the conduction band by calculating the quantum states of the conduction band of the QDs 130 of various particle diameters (i.e., various diameters). The relationship between the average particle diameter of the QDs 130 and the emission wavelength of the QDs 130 can be determined from an energy gap between the ground state of the conduction band and the ground state of the valence band by calculating the quantum states of the conduction band and the valence band of the QDs 130 of various particle diameters.

The display device 1 in accordance with the present embodiment hence exhibits a higher light-emission efficiency than conventional display devices when a composition of the QD material for the QDs 130 and an acceptable range of the average particle diameter of the QDs 130 are selected from ranges applicable to display devices based on the relationship between the energy gap ΔE of the QDs 130 and the average particle diameter of the QDs 130 and on the relationship between the average particle diameter of the QDs 130 and the emission wavelength of the QDs 130.

The average particle diameter QDs 130 may be alternatively calculated from an electronic microscope.

A description will be given next of an exemplary method of manufacturing the light-emitting layer 13.

The QDs 130 in the light-emitting layer 13 in accordance with the present embodiment are an application-type of QDs formed by a solution technique, as described earlier. The light-emitting layer 13 is formed by applying the liquid composition 100 to the top face of the hole transport layer 14 and drying the liquid composition 100.

The liquid composition 100 used in the formation of the light-emitting layer 13 is first added to the medium 132 of the QDs 130. Subsequently, the ligands 131 are also added to the medium 132. The ligands 131, serving as a dispersant, enables efficient dispersion of the QDs 130 in the medium 132. The ligands 131 are added to the medium 132 in a suitable amount that is not limited in any particular manner and that may be so specified in accordance with the QD material and the average particle diameter of the QDs as to suppress aggregation of the QDs 130. As an example, the ligands 131 are added in an amount of from 0.1 parts by weight to 100 parts by weight, both inclusive, per every 100 parts by weight of the QDs 130.

The liquid composition 100 may contain, as well as the QDs 130, the ligands 131, and the medium 132, for example, a polymer-based surface-modifying compound (e.g., a surface-modifying compound of a chain-like polymer) including a chain-like polymer in which monomer molecules are repeated (linearly) like rings in a chain. The surface-modifying compound has a molecular weight greater than or equal to 10,000 as an example. The surface-modifying compound may be, for example, polyvinylpyrrolidone (PVP), polyethylene glycol (PEG), or polystyrene (PS). The liquid composition 100, when additionally containing such a surface-modifying compound, can physically stabilize the QDs 130 in solidifying the liquid composition 100 (in other words, in forming the light-emitting layer 13).

The surface-modifying compound remains in the light-emitting layer 13 as a solid component upon the formation of the light-emitting layer 13. Therefore, if the surface-modifying compound is present in an excessive amount relative to the QDs 130, the surface-modifying compound disrupts the injection of carriers to the QDs 130. For these reasons, when the liquid composition 100 additionally contains the surface-modifying compound, the surface-modifying compound is present preferably in an amount of from 0.1 parts by weight to 50 parts by weight, both inclusive, per every 100 parts by weight of the QDs 130.

The liquid composition 100 is applied to the top face of the hole transport layer 14 by a publicly known application method such as inkjet technology or spin-coating. Accordingly, the method of manufacturing the light-emitting element 10 includes an application step of applying the liquid composition 100. The method of manufacturing the light-emitting element 10 further includes a film forming step of forming the light-emitting layer 13 by from the liquid composition 100 applied in the application step.

The quantity of the medium 132 relative to the QDs 130 and the ligands 131 is not limited in any particular manner. Note however that if the liquid composition 100 has a very low viscosity (e.g., less than 0.01 Pa·s (=0.1 cp)), it becomes difficult to fix a film of the applied liquid composition 100 to the top face of the hole transport layer 14 and hence difficult to form the light-emitting layer 13. The “viscosity of the liquid composition 100” refers to the viscosity of the liquid composition 100 before the liquid composition 100 is solidified (i.e., before the liquid composition 100 is cured) (refers to the viscosity of the liquid composition 100 when the liquid composition 100 contains a sufficient amount of the medium 132).

Meanwhile, if the liquid composition 100 has a very high viscosity (e.g., greater than 2 Pa·s (=20 cp)) and is applied by inkjet technology, the liquid composition 100 may clog the nozzle ejecting the liquid composition 100, which would make it difficult to form the light-emitting layer 13.

For these reasons, the quantity of the medium 132 is specified in a suitable manner such that, for example, the liquid composition 100 has a viscosity in the range described here. The viscosity of the liquid composition 100 may be adjusted by adding a thickening agent to the medium 132.

The film of the liquid composition 100 prepared by applying the liquid composition 100 to the top face of the hole transport layer 14 is solidified (cured) as a result of naturally drying the film or otherwise volatilizing the medium 132, which concludes the formation the light-emitting layer 13 containing the QDs 130 and the ligands 131.

A specific description is now given of the light-emitting element 10 in accordance with the present embodiment by way of examples. The following examples are mere examples of the light-emitting element 10 in accordance with the present embodiment and by no means limit the scope of the present embodiment.

In the following examples, the quantum states of the conduction band and the valence band are calculated by solving a single-band Schrodinger equation as described earlier.

### EXAMPLE 1

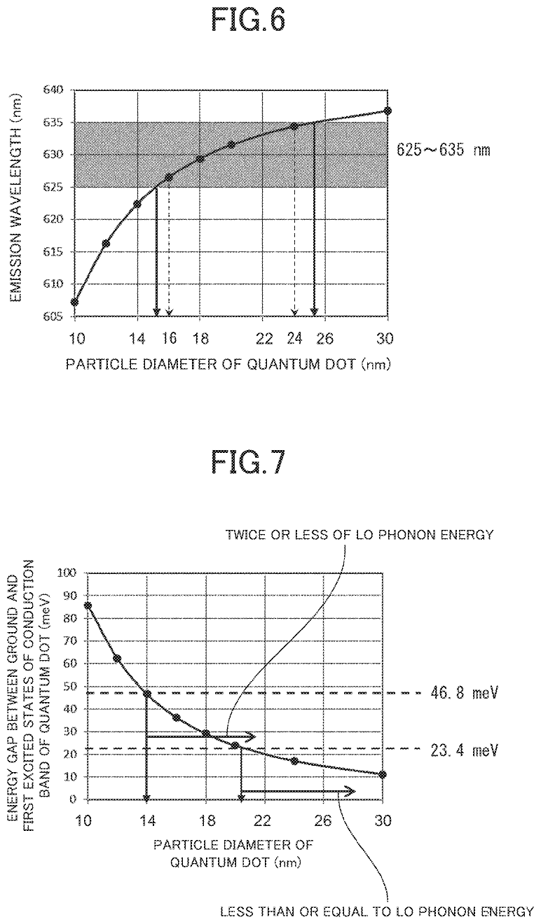

FIG. 5 is a graph representing a relationship between the particle diameter of QDs and the energy gap ΔE of the QDs when the QDs are made of Cd_{0.7}Zn_{0.3}Se. FIG. 6 is a graph representing a relationship between the particle diameter and the emission wavelength of the Cd_{0.7}Zn_{0.3}Se QDs.

CdSe has an LO phonon energy of 26 meV. ZnSe has an LO phonon energy of 31.4 meV. Cd_{0.7}Zn_{0.3}Se has an LO phonon energy of 27.6 meV as approximately calculated from the LO phonon energy of CdSe and ZnSe bar linear interpolation.

FIG. 5 shows that the energy gap ΔE of the Cd_{0.7}Zn_{0.3}Se QDs can be reduced by increasing the particle diameter of the QDs.

The Cd_{0.7}Zn_{0.3}Se QDs have an energy gap ΔE of 55.2 meV, which is equal to twice the LO phonon energy of Cd_{0.7}Zn_{0.3}Se, when the QDs have a particle diameter of 13.8 nm and an energy gap ΔE of 53.9 meV when the QDs have a particle diameter of 14 nm. The energy gap ΔE of the QIN is therefore less than or equal to twice the LO phonon energy when the average particle diameter of the QDs is greater than or equal to 14 nm in the present example. Hence, when the QDs are made of Cd_{0.7}Zn_{0.3}Se and have an average particle diameter greater than or equal to 14 nm, the electrons in the first excited state of the conduction band of the QDs efficiently relax to the ground state of the conduction band of the QDs, thereby achieving efficient emission.

Meanwhile, FIG. 6 shows that the Cd_{0.7}Zn_{0.3}Se QDs emit light with a wavelength in the range of 630 nm±5 nm (i.e., from 625 to 635 nm; 630 nm is the red wavelength defined in the BT. 2020 international standard) at least when the QDs have a particle diameter in the range of 16 to 24 nm. Specifically, the emission wavelength is 626.5 nm when the particle diameter is 16 nm and 634.4 nm when the particle diameter is 24 nm. Therefore, the QDs efficiently emit light with the red wavelength defined in the BT. 2020 international standard when the QDs are made of Cd_{0.7}Zn_{0.3}Se and have an average particle diameter of 16 to 24 nm.

The QDs have an energy gap ΔE of 27.6 meV when the QDs have a particle diameter of 20 nm. The energy gap ΔE of the QDs shown in FIG. 5 is less than or equal to 27.6 meV, which is equal to 1 time the LO phonon energy. The QDs therefore have an energy gap ΔE less than or equal to 1 time the LO phonon energy when the QDs have a particle diameter greater than or equal to 20 nm in the present example. Hence, when the Cd_{0.7}Zn_{0.3}Se QDs have an average particle diameter greater than or equal to 20 nm, the electrons in the first excited state of the conduction band of the QDs more efficiently relax to the ground state of the conduction band of the QDs, thereby achieving more efficient emission.

It is therefore understood that the Cd_{0.7}Zn_{0.3}Se QDs more efficiently emit light with the red wavelength defined in the BT. 2020 international standard when the QDs have an average particle diameter of 20 to 24 nm.

### EXAMPLE 2

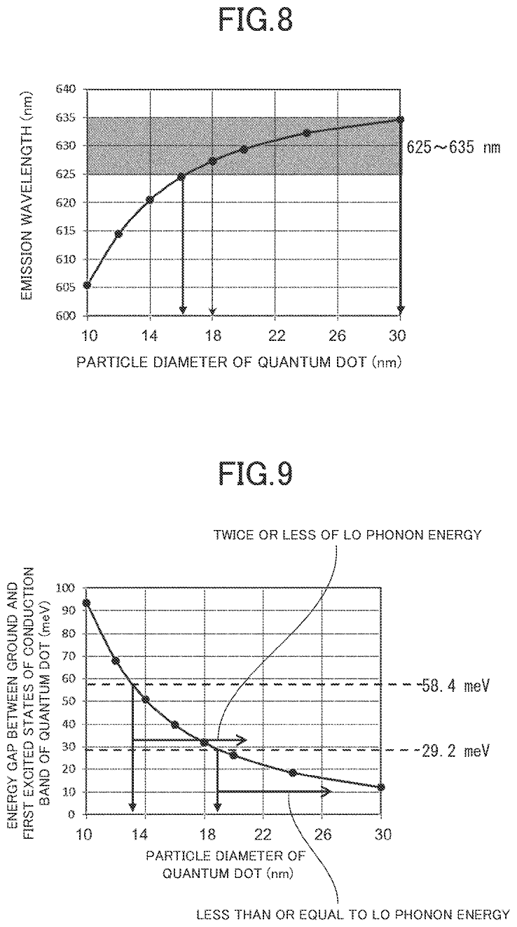

FIG. 7 is a graph representing a relationship between the particle diameter of QDs and the energy gap ΔE of the QDs when the QDs are made of Cd_{0.55}Zn_{0.45}Te. FIG. 8 is a graph representing a relationship between the particle diameter and the emission wavelength of the Cd_{0.55}Zn_{0.45}Te QDs.

CdTe has an LO phonon energy of 21.3 meV. ZnTe has an LO phonon energy of 26 meV. Cd_{0.55}Zn_{0.45}Te has an LO phonon energy of 23.4 meV as approximately calculated from the LO phonon energy of CdTe and ZnTe by linear interpolation.

FIG. 7 shows that the energy gap ΔE of the Cd_{0.55}Zn_{0.45}Te QDs can be reduced by increasing the particle diameter of the QDs.

FIG. 7 also shows that the Cd_{0.55}Zn_{0.45}Te QDs have an energy gap ΔE of 46.8 meV, which is equal to twice the LO phonon energy of Cd_{0.55}Zn_{0.45}Te, when the QDs have a particle diameter of 14.0 nm. The energy gap ΔE of the QDs is therefore less than or equal to twice the LO phonon energy when the average particle diameter of the QDs is greater than or equal to 14 nm in the present example. Hence, when the QDs are made of Cd_{0.55}Zn_{0.45}Te and have an average particle diameter greater than or equal to 14 nm, the electrons in the first excited state of the conduction band of the QDs efficiently relax to the ground state of the conduction band of the QDs, thereby achieving efficient emission.

Meanwhile, FIG. 8 shows that the Cd_{0.55}Zn_{0.45}Te QDs emit light with a wavelength in the range of 630 nm±5 nm (i.e., from 625 to 635 nm; 630 nm is the red wavelength defined in the BT. 2020 international standard) at least when the QDs have a particle diameter in the range of 18 to 30 nm. Therefore, the QDs efficiently emit light with the red wavelength defined in the BT. 2020 international standard when the QDs are made of Cd_{0.55}Zn_{0.45}Te and have an average particle diameter of 18 to 30 nm.

The energy gap ΔE of the QDs shown in FIG. 7 is 23.4 meV, which is equal to 1 time the LO phonon energy, when the particle diameter of the QDs is 20.3 may. Therefore, in the present example, the energy gap ΔE of the QDs is less than or equal to 1 time the LO phonon energy when the QDs have a particle diameter greater than or equal to 21 nm (i.e., when the QDs have an average particle diameter greater than or equal to 21 nm). Hence, when the Cd_{0.55}Zn_{0.45}Te QDs have an average particle diameter greater than or equal to 21 nm, the electrons in the first excited state of the conduction band of the QDs more efficiently relax to the ground state of the conduction band of the QDs, thereby achieving more efficient emission.

It is therefore understood that the Cd_{0.55}Zn_{0.45}Te QDs more efficiently emit light with the red wavelength defined in the BT. 2020 international standard when the QDs have an average particle diameter of 21 to 30 nm.

### EXAMPLE 3

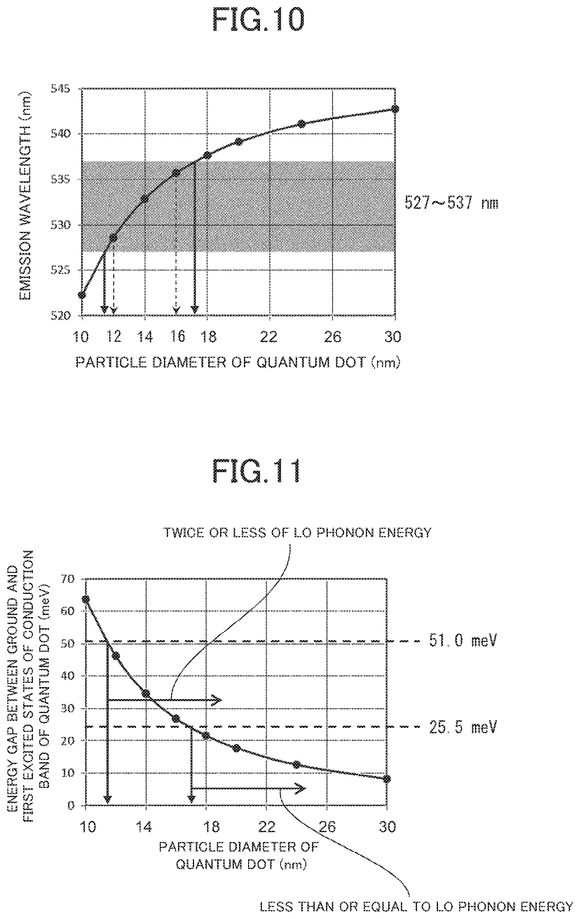

FIG. 9 is a graph representing a relationship between the particle diameter of QDs and the energy gap ΔE of the QDs when the QDs are made of Cd_{0.4}Zn_{0.6}Se. FIG. 10 is a graph representing a relationship between the particle diameter and the emission wavelength of the Cd_{0.4}Zn_{0.6}Se QDs.

Cd_{0.4}Zn_{0.6}Se has an LO phonon energy of 29.2 meV as approximately calculated, similarly to Example 1, from the LO phonon energy of CdSe (26 meV) and the LO phonon energy of ZnSe (31.4 meV) by linear interpolation.

FIG. 9 shows that the energy gap ΔE of the Cd_{0.4}Zn_{0.6}Se QDs can be reduced by increasing the average diameter of the QDs.

The Cd_{0.4}Zn_{0.6}Se QDs have an energy gap ΔE of 58.4 meV, which is equal to twice the LO phonon energy of Cd_{0.4}Zn_{0.6}Se, when the QDs have a particle diameter of 13.0 nm. Therefore, in the present example, the energy gap ΔE of the QDs is less than or equal to twice the LO phonon energy when the QDs have a particle diameter greater than or equal to 13 nm (i.e., when the QDs have an average particle diameter greater than or equal to 13 nm). Hence, when the QDs are made of Cd_{0.4}Zn_{0.6}Se and have an average particle diameter greater than or equal to 13 nm, the electrons in the first excited state of the conduction band of the QDs efficiently relax to the ground state of the conduction band of the QDs, thereby achieving efficient emission.

Meanwhile, FIG. 10 shows that the Cd_{0.4}Zn_{0.6}Se QDs emit light with a wavelength in the range of 532 nm±5 nm (i.e.., from 527 to 537 nm; 532 nm is the green wavelength defined in the BT. 2020 international standard) at least when the QDs have a particle diameter in the range of 12 to 16 nm. Therefore, the QDs efficiently emit light with the green wavelength defined in the BT. 2020 international standard when the QDs are made of Cd_{0.4}Zn_{0.6}Se and have an average particle diameter of 13 to 16 nm.

The energy gap ΔE of the QDs shown in FIG. 9 is 29.2 meV, which is equal to 1 time the LO phonon energy, when the particle diameter of the QDs is 18.8 nm. Therefore, in the present example, the energy gap ΔE of the QDs is less than or equal to 1 time the LO phonon energy when the QDs have a particle diameter greater than or equal to 19 nm (i.e., when the QDs have an average particle diameter greater than or equal to 19 nm). Hence, when the Cd_{0.4}Zn_{0.6}Se QDs have an average particle diameter greater than or equal to 19 nm, the electrons in the first excited state of the conduction band of the QDs more efficiently relax to the ground state of the conduction band of the QDs, thereby achieving more efficient emission.

It should be noted however that the QDs preferably have an average particle diameter of 14 to 16 nm to achieve efficient emission with the green wavelength defined in the BT. 2020 international standard as described earlier. It is therefore understood that the Cd_{0.4}Zn_{0.6}Se QDs exhibit the highest light-emission efficiency at the green wavelength defined in the BT. 2020 international standard when the QDs have an average particle diameter of 13 to 16 nm.

### EXAMPLE 4

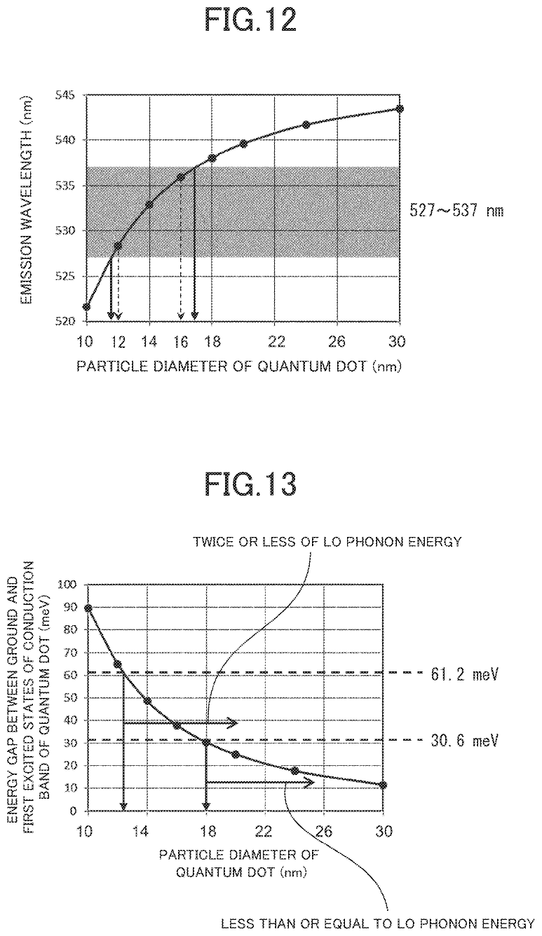

FIG. 11 is a graph representing a relationship between the particle diameter of QDs and the energy gap ΔE of the QDs when the QDs are made of Cd_{0.1}Zn_{0.9}Te. FIG. 12 is a graph representing a relationship between the particle diameter and the emission wavelength of the Cd_{0.1}Zn_{0.9}Te QDs.

Cd_{0.1}Zn_{0.9}Te has an LO phonon energy of 25.5 meV as approximately calculated, similarly to Example 2, from the LO phonon energy of CdTe (21.3 meV) and the LO phonon energy of ZnTe (26 meV) by linear interpolation.

FIG. 11 shows that the energy gap ΔE of the of Cd_{0.1}Zn_{0.9}Te QDs can be reduced by increasing the average diameter of the QDs.

The Cd_{0.1}Zn_{0.9}Te QDs have an energy gap ΔE of 51.0 meV, which is equal to twice the LO phonon energy of Cd_{0.1}Zn_{0.9}Te, when the QDs have a particle diameter of 11.4 nm. Therefore, in the present example, the energy gap ΔE of the QDs is less than or equal to twice the LO phonon energy when the QDs have a particle diameter greater than or equal to 12 nm (i.e., when the QDs have an average particle diameter greater than or equal to 12 nm). Hence, when the QDs are made of Cd_{0.1}Zn_{0.9}Te and have an average particle diameter greater than or equal to 12 nm, the electrons in the first excited state of the conduction hand of the QDs efficiently relax to the ground state of the conduction band of the QDs, thereby achieving efficient emission.

Meanwhile, FIG. 12 shows that the Cd_{0.1}Zn_{0.9}Te QDs emit light with a wavelength in the range of 532 nm±5 nm (i.e., from 527 to 537 nm; 532 nm is the green wavelength defined in the BT. 2020 international standard) at least when the QDs have a particle diameter in the range of 12 to 16 nm. Therefore, the QDs efficiently emit light with the green wavelength defined in the BT. 2020 international standard when the QDs are made of Cd_{0.1}Zn_{0.9}Te and have an average diameter of 12 to 16 nm.

The energy gap ΔE of the QDs shown in FIG. 11 is 25.5 meV, which is equal to 1 time the LO phonon energy, when the particle diameter of the QDs is 16.5 nm. Therefore, in the present example, the energy gap ΔE of the QDs is less than or equal to 1 time the LO phonon energy when the QDs have a particle diameter greater than or equal to 17 nm (i.e., when the QDs have an average particle diameter greater than or equal to 17 nm). Hence, when the Cd_{0.1}Zn_{0.9}Te QDs have an average particle diameter greater than or equal to 17 nm, the electrons in the first excited state of the conduction hand of the QDs more efficiently relax to the ground state of the conduction hand of the QDs, thereby achieving more efficient emission.

It should be noted however that the QDs preferably have an average particle diameter of 12 to 16 nm to achieve efficient emission with the green wavelength defined in the BT. 2020 international standard as described earlier. It is therefore understood that the Cd_{0.1}Zn_{0.9}Te QDs exhibit the highest light-emission efficiency when the QDs have an average particle diameter of 12 to 16 nm.

### EXAMPLE 5

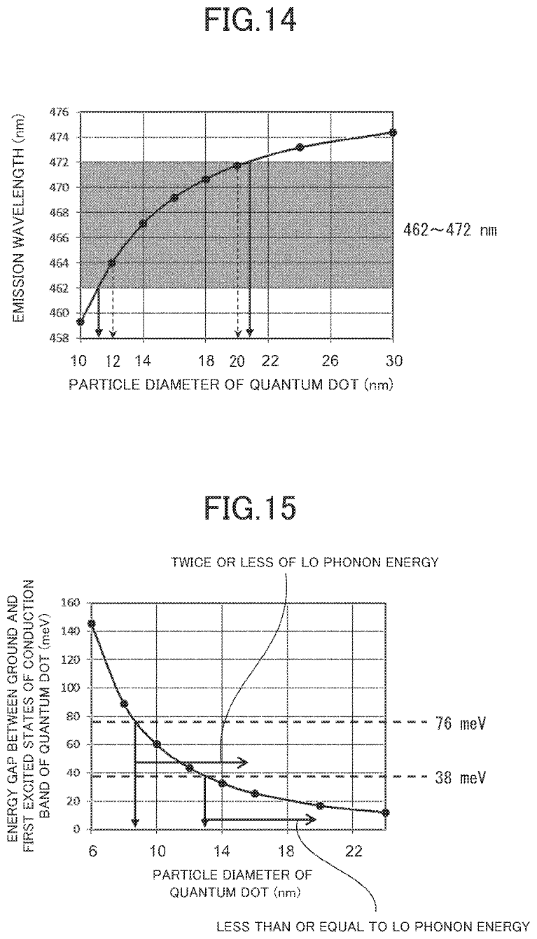

FIG. 13 is a graph representing a relationship between the particle diameter of QDs and the energy gap ΔE of the QDs when the QDs are made of Cd_{0.15}Zn_{0.85}Se. FIG. 14 is a graph representing a relationship between the particle diameter and the emission wavelength of the Cd_{0.15}Zn_{0.85}Se QDs.

Cd_{0.15}Zn_{0.85}Se has an LO phonon energy of 30.6 meV as approximately calculated, similarly to Example 1, from the LO phonon energy of CdSe (26 meV) and the LO phonon energy of ZnSe (31.4 meV) by linear interpolation.

FIG. 13 shows that the energy gap ΔE of the Cd_{0.15}Zn_{0.85}Se QDs can be reduced by increasing the average diameter of the QDs.

The Cd_{0.15}Zn_{0.85}Se QDs have an energy gap ΔE of 61.2 meV, which is equal to twice the LO phonon energy of Cd_{0.15}Zn_{0.85}Se, when the QDs have a particle diameter of 12.4 nm. Therefore, in the present example, the energy gap ΔE of the QDs is less than or equal to twice the LO phonon energy when the QDs have a particle diameter greater than or equal to 13 nm (i.e., when the QDs have an average particle diameter greater than or equal to 13 nm). Hence, when the QDs are made of Cd_{0.15}Zn_{0.85}Se and have an average particle diameter greater than or equal to 13 nm, the electrons in the first excited state of the conduction band of the QDs efficiently relax to the ground state of the conduction band of the QDs, thereby achieving efficient emission.

Meanwhile, FIG. 14 shows that the Cd_{0.15}Zn_{0.85}Se QDs emit light with a wavelength in the range of 467 nm±5 nm (i.e., from 462 to 472 nm; 467 nm is the blue wavelength defined in the BT. 2020 international standard) at least when the QDs have a particle diameter in the range of 12 to 20 nm. Therefore, the QDs efficiently emit light with the blue wavelength defined in the BT. 2020 international standard when the QDs are made of Cd_{0.15}Zn_{0.85}Se and have an average diameter of 14 to 20 nm.

FIG. 13 also shows that the energy gap ΔE of the QDs is 30.6 meV, which is equal to 1 time the LO phonon energy; when the particle diameter of the QDs is 18.0 nm. Therefore, in the present example, the energy gap ΔE of the QDs is less than or equal to 1 time the LO phonon energy when the QDs have a particle diameter greater than or equal to 18 nm (i.e., when the QDs have an average particle diameter greater than or equal to 18 nm). Hence, when the Cd_{0.15}Zn_{0.85}Se QDs have an average particle diameter greater than or equal to 18 nm, the electrons in the first excited state of the conduction band of the QDs more efficiently relax to the ground state of the conduction band of the QDs, thereby achieving more efficient emission.

It is therefore understood that the Cd_{0.15}Zn_{0.85}Se QDs more efficiently emit light with the blue wavelength defined in the BT. 2020 international standard when the QDs have an average particle diameter of 18 to 20 nm.

### EXAMPLE 6

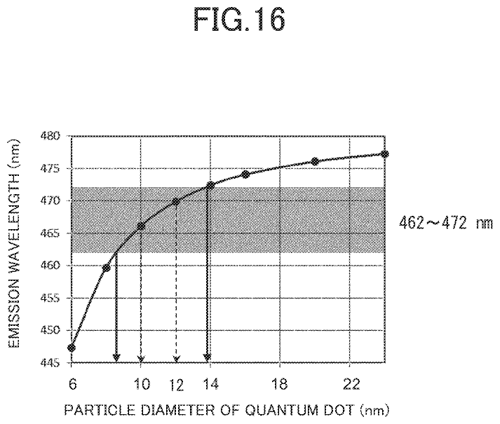

FIG. 15 is a graph representing a relationship between the particle diameter of QDs and the energy gap ΔE of the QDs when the QDs are made of CdS. FIG. 16 is a graph representing a relationship between the particle diameter and the emission wavelength of the CdS QDs.

CdS has an LO phonon energy of 38 meV FIG. 15 shows that the energy gap ΔE of the CdS QDs can be reduced by increasing the average diameter of the QDs.

The CdS QDs have an energy gap ΔE of 76 meV, which is equal to twice the LO phonon energy of CdS, when the QDs have a particle diameter of 8.7 nm. Therefore, in the present example, the energy gap ΔE of the QDs is less than or equal to twice the LO phonon energy when the QDs have a particle diameter greater than or equal to 9 nm (i.e., when the QDs have an average particle diameter greater than or equal to 9 nm). Hence, when the QDs are made of CdS and have an average diameter greater than or equal to 9 nm, the electrons in the first excited state of the conduction band of the QDs efficiently relax to the ground state of the conduction band of the QDs, thereby achieving efficient emission.

Meanwhile, FIG. 16 shows that the CdS QDs emit light with a wavelength in the range of 467 nm±5 nm (i.e., 462 to 472 nm; 467 nm is the blue wavelength defined in the BT. 2020 international standard) at least when the QDs have a particle diameter in the range of 10 to 12 nm. Therefore, the QDs efficiently emit light with the blue wavelength defined in the BT. 2020 international standard when the QDs are made of CdS and have an average particle diameter of 10 to 12 nm.

The energy gap ΔE of the QDs shown in FIG. 15 is 38 meV, which is equal to 1 time the LO phonon energy, when the particle diameter of the QDs is 13.0 mm. Therefore, in the present example, the energy gap ΔE of the QDs is less than or equal to 1 time the LO phonon energy when the QDs have a particle diameter greater than or equal to 13 nm (i.e., when the QDs have an average particle diameter greater than or equal to 13 nm). Hence, when the CdS QDs have an average diameter greater than or equal to 13 nm, the electrons in the first excited state of the conduction band of the QDs more efficiently relax to the ground state of the conduction band of the QDs, thereby achieving more efficient emission.

It should be noted however that the QDs preferably have an average diameter of 10 to 12 nm to achieve efficient emission with the blue wavelength defined in the BT. 2020 international standard as described earlier. It is therefore understood that the CdS QDs exhibit the highest light-emission efficiency when the QDs have an average diameter of 10 to 12 nm.

The present invention is not limited to the description of the embodiments above and may be altered within the scope of the claims. Embodiments based on a proper combination of technical means disclosed in different embodiments are encompassed in the technical scope of the present invention. Furthermore, new technological features can be created by combining different technical means disclosed in the embodiments.

### REFERENCE SIGNS LIST

1 Display Device
10 Light-emitting Element
11 First Electrode (Cathode)
13 Light-emitting Layer
16 Second Electrode (Anode)
130 QD (Quantum Dot)
131 Ligand

1. A light-emitting element comprising:
an anode;
a cathode; and
a light-emitting layer between the anode and the cathode, wherein
the light-emitting layer contains quantum dots, and
the quantum dots have a number average particle diameter greater than or equal to D_{LO2} and less than or equal to 100 nm, where D_{LO2} is a particle diameter of the quantum dots when the quantum dots exhibit an energy gap, between a ground state and a first excited state of a conduction band thereof, that is equivalent to twice an LO phonon energy of a material for the quantum dots.

2-4. (canceled)

5. The light-emitting element according to claim 1, wherein
the quantum dots each contain Cd and Zn, and
the quantum dots have a number average particle diameter greater than or equal to 14 nm and less than or equal to 100 nm.

6-7. (canceled)

8. The light-emitting element according to claim 1, wherein
the quantum dots are made of CdS, and
the quantum dots have a number average particle diameter greater than or equal to 9 nm and less than or equal to 100 nm.

9-14. (canceled)

15. The light-emitting element according to claim 1, wherein
the quantum dots are made of a species or a combination of species selected from Cd (cadmium), S (sulfur), Te (tellurium), Se (selenium), Zn (zinc), In (indium), N (nitrogen), P (phosphorus), As (arsenic), Sb (antimony), Al (aluminum), Ga (gallium), Pb (lead), Si (silicon), Ge (germanium), and Mg (magnesium).

16. A light-emitting element comprising:
an anode;
a cathode; and
a light-emitting layer between the anode and the cathode, wherein
the light-emitting layer contains quantum dots, and
the quantum dots each contain Zn.

17. A display device comprising:
the light-emitting element according to claim 16; and
pixels including plural types of the light-emitting elements that exhibit different emission wavelengths, wherein
the plural types of the light-emitting elements emit light of a shorter wavelength when the quantum dots in the plural types of the light-emitting elements have a higher Zn composition ratio.

18. The display device according to claim 17, wherein the quantum dots each contain Cd.

19. The display device according to claim 17, wherein
the plural types of the light-emitting elements include a light-emitting element that emits red light, and
in the red-light-emitting element, the quantum dots have a number average particle diameter greater than or equal to 18 nm and less than or equal to 24 nm.

20. The display device according to claim 17, wherein
the plural types of the light-emitting elements include a light-emitting element that emits green light, and
in the green-light-emitting element, the quantum dots have a number average particle diameter greater than or equal to 12 nm and less than or equal to 16 nm.

21. The display device according to claim 17, wherein
the plural types of the light-emitting elements include a light-emitting element that emits blue light, and
in the blue-light-emitting element, the quantum dots have a number average particle diameter greater than or equal to 12 nm and less than or equal to 20 nm.

22. The display device according to claim 18, wherein
the plural types of the light-emitting elements include a light-emitting element that emits red light, and
in the red-light-emitting element, the quantum dots have a number average particle diameter greater than or equal to 18 nm and less than or equal to 24 nm.

23. The display device according to claim 18, wherein
the plural types of the light-emitting elements include a light-emitting element that emits green light, and
in the green-light-emitting element, the quantum dots have a number average particle diameter greater than or equal to 12 nm and less than or equal to 16 nm.

24. The display device according to claim 18, wherein
the plural types of the light-emitting elements include a light-emitting element that emits blue light, and
in the blue-light-emitting element, the quantum dots have a number average particle diameter greater than or equal to 12 nm and less than or equal to 20 nm.

25. The light-emitting element according to claim 16, wherein the quantum dots have a number average particle diameter greater than or equal to 21 nm and less than or equal to 100 nm.

26. The display device according to claim 25, wherein the quantum dots each contain Cd.

27. The light-emitting element according to claim 16, wherein the quantum dots have a number average particle diameter greater than or equal to D_{LO2} and less than or equal to 100 nm, where D_{LO2} is a particle diameter of the quantum dots when the quantum dots exhibit an energy gap, between a ground state and a first excited state of a conduction band thereof, that is equivalent to twice an LO phonon energy of a material for the quantum dots.

28. A light-emitting element comprising:
an anode;
a cathode; and
a light-emitting layer between the anode and the cathode, wherein
the light-emitting layer contains quantum dots, and
the quantum dots are made of CdS.

29. The light-emitting element according to claim 28, wherein the quantum dots have a number average particle diameter greater than or equal to 13 nm and less than or equal to 100 nm.

30. The light-emitting element according to claim 28, wherein
the light-emitting element emits blue light, and
in the blue-light-emitting element, the quantum dots have a number average particle diameter greater than or equal to 10 nm and less than or equal to 12 nm.

31. The light-emitting element according to claim 28, wherein the quantum dots have a number average particle diameter greater than or equal to D_{LO2} and less than or equal to 100 nm, where D_{LO2} is a particle diameter of the quantum dots when the quantum dots exhibit an energy gap, between a ground state and a first excited state of a conduction band thereof, that is equivalent to twice an LO phonon energy of a material for the quantum dots.
